(19) United States
(12) Patent Application Publication
(10) Pub. No.: US 2026/0120915 A1
(43) Pub. Date: Apr. 30, 2026

(54) CONTACT STRUCTURE WITH FLEXIBLE DIELECTRIC BARRIER

(71) Applicant: INTERNATIONAL BUSINESS MACHINES CORPORATION, ARMONK, NY (US)

(72) Inventors: Nicholas Latham, Albany, NY (US); Alexander Hamer, Saratoga Springs, NY (US); Kishan Jayanand, COHOES, NY (US); Nicholas Alexander POLOMOFF, Hopewell Junction, NY (US); Chih-Chao Yang, Glenmont, NY (US); Ashim Dutta, Clifton Park, NY (US)

(21) Appl. No.: 18/929,716

(22) Filed: Oct. 29, 2024

(51) Int. Cl. H01L 23/00; H01B 5/14

(52) U.S. Cl. CPC H01B 5/14; H10W 72/01953; H10W 72/01955; H10W 72/923; H10W 72/924; H10W 72/932; H10W 72/952

(57) ABSTRACT

A contact structure and a method of forming the contact structure. The contact structure includes: a metallic contact; a flexible dielectric material; and an interlevel dielectric material surrounding, and in direct contact with, both the metallic contact and the flexible dielectric material. The flexible dielectric material has a lower modulus of elasticity than does the interlevel dielectric material. The flexible dielectric material and the interlevel dielectric material are different dielectric materials. The flexible dielectric material may be positioned to be compressed in response to a shearing force generated at an interface between the flexible dielectric material and the metallic contact during expansion of the metallic contact. The metallic contact may include a bottom portion and a top portion, wherein the top portion includes an upper part and a lower part, and wherein the flexible dielectric material is in direct contact with the lower part of the top portion.

### BACKGROUND

The present invention relates generally to a bond contact, and more specifically to a contact structure having a metallic contact such that a flexible dielectric material surrounds, in direct contact with, the metallic contact.

### SUMMARY

Embodiments of the present invention provide contact structure and a method of forming the contact structure. The contact structure includes: a metallic contact; a flexible dielectric material; and an interlevel dielectric material surrounding, and in direct contact with, both the metallic contact and the flexible dielectric material. The flexible dielectric material and the interlevel dielectric material are different dielectric materials.

In embodiments, the flexible dielectric material is positioned to be compressed in response to a shearing force generated at an interface between the flexible dielectric material and the metallic contact during expansion of the metallic contact.

In embodiments, the metallic contact includes a bottom portion and a top portion, wherein the top portion comprises an upper part and a lower part, and wherein the flexible dielectric material is in direct contact with the lower part of the top portion of the metallic contact.

### BRIEF DESCRIPTION OF THE DRAWINGS

FIG. 1 depicts a stress buildup and resultant formation of voids at an interface between a copper contact and a dielectric material of tetraethyl orthosilicate (TEOS), in accordance with the prior art.

FIGS. 2-10 depict a process of forming a contact structure, in accordance with embodiments of the present invention.

FIG. 2 depicts an initial configuration of the contact structure which includes a metallic contact, an interlevel dielectric material, a photoresist, and a via.

FIG. 3 depicts the contact structure of FIG. 2 after the photoresist has been removed and a flexible dielectric material has been inserted into the via, in accordance with embodiments of the present invention.

FIG. 4 depicts the contact structure of FIG. 3 after a second portion of the flexible dielectric material has been removed, in accordance with embodiments of the present invention.

FIG. 5 depicts the contact structure of FIG. 4 after an upper part of the first portion of flexible dielectric material has been selectively etched away by an etch process, leaving a first remaining portion of the flexible dielectric material, in accordance with embodiments of the present invention.

FIG. 6 depicts the contact structure of FIG. 5 after a photoresist is patterned on top of the interlevel dielectric material and a portion of the first remaining portion of the flexible dielectric material, leaving a via above a portion of the first remaining portion of the flexible dielectric material, in accordance with embodiments of the present invention.

FIG. 7A depicts the contact structure of FIG. 6 after a portion of the first remaining portion of the flexible dielectric material has been etched away by an etching process using the photoresist, and after the photoresist has been removed in conjunction with a chemical mechanical polishing (CMP) process that has planarized a top surface of the metallic contact, in accordance with embodiments of the present invention.

FIG. 7B is a top view of the contact structure of FIG. 7A, in accordance with embodiments of the present invention.

FIG. 8A depicts the contact structure of FIG. 7A after a second metal has been inserted into the via to fill and overflow the via, followed by a CMP process to planarize the top surface of the contact structure, in accordance with embodiments of the present invention.

FIG. 8B is a top view of the contact structure of FIG. 8A, in accordance with embodiments of the present invention.

FIGS. 9A, 9B and 9C are each a vertical cross-sectional view of the contact structure that includes one conductive contact of the multiple conductive contacts in FIG. 8A, surrounding flexible dielectric material, and surrounding interlevel dielectric material 30, in accordance with embodiments of the present invention.

FIG. 10 is a flow chart of a method for forming a contact structure, in accordance with embodiments of the present invention.

### DETAILED DESCRIPTION

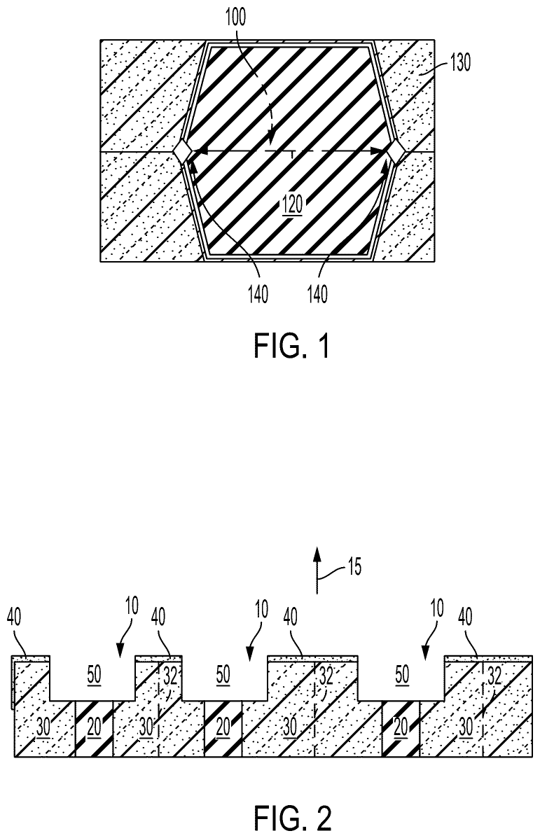

FIG. 1 depicts a stress buildup 100 and resultant formation of voids 140 at an interface between a copper contact 120 and a dielectric material 130 of tetraethyl orthosilicate (TEOS), in accordance with the prior art. The stress buildup 100 is due to a thermal expansion of the copper contact 120 during a thermal bonding process (e.g., annealing). The thermal stress is transferred from the center to the edge of the copper contact 120 during the bonding (e.g., annealing) of the copper contact 120 to another contact (e.g., a contact of a bond device or of a carrier).

More generally, a metallic contact comprising a metal such as inter alia copper is surrounded by, and is in direct mechanical contact with, an interlevel dielectric material such as inter alia tetraethyl orthosilicate (TEOS), silicon dioxide (SiO₂, fluorinated silicon dioxide (SiOF), silicon nitride (Si₃N₄), etc. The metallic contact may be bonded to another contact (e.g., a contact of a bond device or of a carrier) at a hybrid bond interface during a bonding process such as inter alia an annealing process.

During the bonding process, the metal (e.g., copper) melts and reflows to generate the interface between the bonded components. The bonding process and metal expansion during reflow can cause a thermal stress buildup in the interface of the interlevel dielectric material and the metal. Such thermal stress is compressive and shear in nature, which may lead to void formation at a metal-dielectric interface between the metallic contact and the surrounding interlevel dielectric material or crack initiation in the dielectric surrounding the metal pads on the hybrid bonding surface.

Embodiments of the present invention serve to mitigate and/or prevent such void formation and crack initiation via use of a flexible dielectric material that surrounds a portion of the metallic contact. The flexible dielectric material functions as a barrier dielectric around the edge of the metallic contact. The modulus of elasticity value of the barrier dielectric is such that the flexible dielectric material will be compressed in response to the thermal stress while the thermal stress is transferred from the center to the edge of the metallic contact during the bonding (e.g., annealing) of the metallic contact to the bond device or the carrier contacts. In effect, the flexible dielectric material is positioned such that the flexible dielectric material is compressed in response to a shearing force generated during expansion of the metallic contact at the edges of the metallic contact (i.e., at an interface between the flexible dielectric material and the metallic contact during expansion of the metallic contact).

The modulus of elasticity of the flexible dielectric material is sufficiently small to prevent void formation and crack initiation at a metal-dielectric interface between the metallic contact and the surrounding flexible dielectric material during thermal stress transfer from the center to the edge of the metallic contact during a thermal bonding (e.g., annealing) of the metallic contact to a bond device or to a carrier contact.

In one embodiment, the flexible dielectric material is an organic material such as, inter alia, a polyimide or a polybenzoxazole (PBO).

FIGS. 2-10 depict a process of forming a contact structure 10, in accordance with embodiments of the present invention.

FIG. 2 depicts an initial configuration of the contact structure 10 which includes a metallic contact 20, an interlevel dielectric material 30, a photoresist 40, and a via 50. The metallic contact 20 comprises a first metal (e.g., copper (Cu), silver (Ag), gold (Au), tungsten (W), titanium (Ti), zinc (Zn), etc.).

FIG. 2, as well as FIGS. 3-7, 7A, and 8A depict multiples contact structures 10, wherein the two contact structures 10 in each pair of two adjacent contact structures 10 are separated by the dashed line 32 and share interlevel dielectric material 30. The dashed lines 32 also exist in FIGS. 3-7, 7A, and 8A but are not shown in FIGS. 3-7, 7A, and 8A.

The metallic contact 20 and the flexible dielectric material 60 are not limited to a specific type of geometry.

In one embodiment, the metallic contact 20 and the flexible dielectric material 60 each have a cylindrical geometry with respect to direction 15 which is an axial direction for the cylindrical geometry. The direction 15 is normal to each cross section of the metallic contact 20 and to each cross section of the flexible dielectric material 60. Each cross section of the metallic contact 20 is bounded by a circle, and the width of the metallic contact 20 at each cross section is the diameter of circle. Each cross section of the flexible dielectric material 60 is an annulus, and the width of the flexible dielectric material 60 at each cross section is the radial thickness of the annulus.

In one embodiment, the metallic contact 20 and flexible dielectric material 60 each have a rectangular geometry, wherein each width extends in a direction that is normal to the direction 15.

The interlevel dielectric material 30 may comprise one of: tetraethyl orthosilicate (TEOS) having the chemical formula (C₂H₅O)₄Si, SiOₓ for x=1 or 2, SiCN, SiN, SiOCN, fluorinated silicon dioxide (SiOF), silicon nitride (Si₃N₄), etc.

The metallic contact 20 is surrounded by, and in direct mechanical contact with, the interlevel dielectric material 30.

The photoresist 40 is on and in direct contact with the interlevel dielectric material 30 and is used to selectively etch away interlevel dielectric material 20 to create the via 50. The via 50 is above the metallic contact 20 and is surrounded by the interlevel dielectric material 30.

FIG. 3 depicts the contact structure 10 of FIG. 2 after the photoresist 40 has been removed and a flexible dielectric material 60 has been inserted into the via 50, in accordance with embodiments of the present invention.

A first portion 61 of the flexible dielectric material 60 fills the via 50 and a second portion 62 of the flexible dielectric material 60 is above, and is in direct mechanical contact with, both the interlevel dielectric material 30 and the first portion 61 of the flexible dielectric material 60.

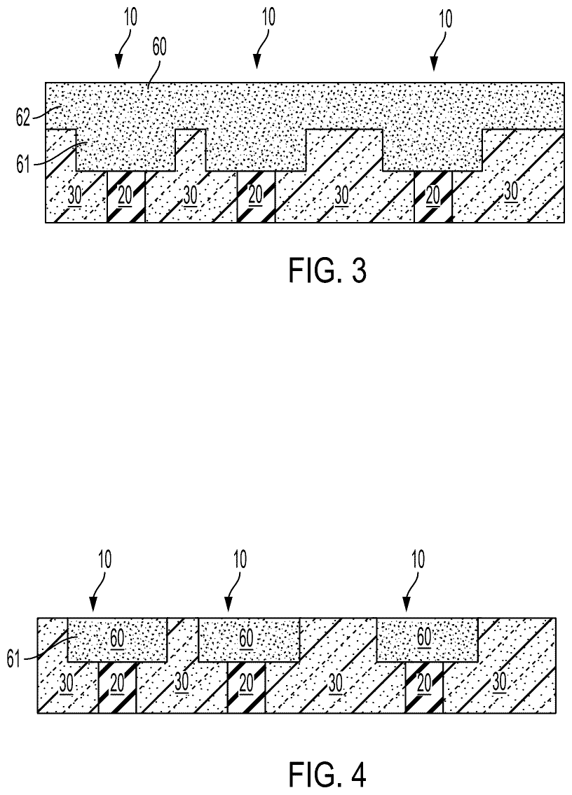

FIG. 4 depicts the contact structure 10 of FIG. 3 after the second portion 62 of the flexible dielectric material 60 has been removed, in accordance with embodiments of the present invention. In one embodiment, the second portion 62 of the flexible dielectric material 60 has been removed by a chemical mechanical polishing (CMP) process that uses a silica slurry to improve, in a controlled manner, the material removal rate (MRR) of the second portion 62 of the flexible dielectric material 60.

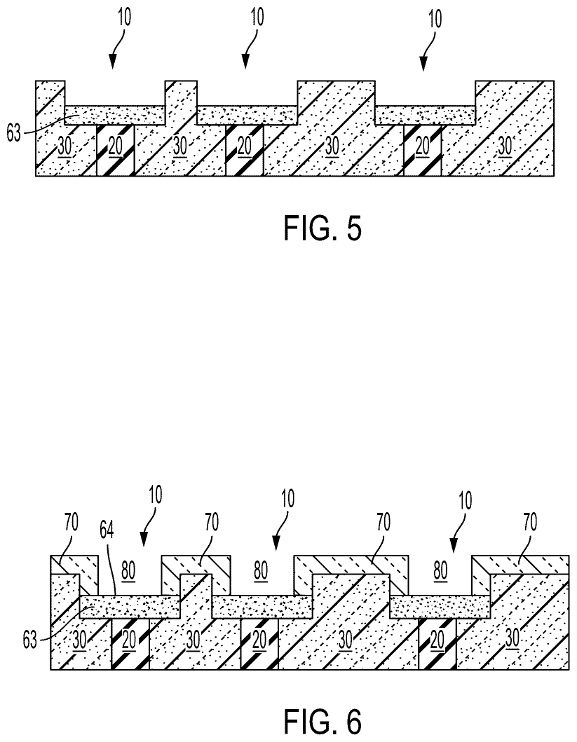

FIG. 5 depicts the contact structure 10 of FIG. 4 after an upper part of the first portion of flexible dielectric material 61 has been selectively etched away by an etch process, leaving a first remaining portion 63 of the flexible dielectric material, in accordance with embodiments of the present invention.

In one embodiment, the etch process that etches the first portion of flexible dielectric material 61 is an O₂—CF₄ plasma etch process.

In one embodiment, the first remaining portion 63 of the flexible dielectric material has a height that is a percent p1 of a total height of the interlevel dielectric material 30. In one embodiment p1 is in a range of 20% to 70%. In one embodiment p1 is in a range of 49% to 51%. In one embodiment p1 is 50%.

There is sufficient selectivity between the flexible dielectric material and the interlevel dielectric material with respect to the etch process that only the flexible dielectric material of the first remaining portion 63, and not the interlevel dielectric material 30, is etched away.

FIG. 6 depicts the contact structure 10 of FIG. 5 after a photoresist 70 is patterned on top of the interlevel dielectric material 30 and a portion of the first remaining portion 63 of the flexible dielectric material 60, leaving a via 80 above a portion of the first remaining portion 63 of the flexible dielectric material 60, in accordance with embodiments of the present invention.

A sufficiently poor etch selectivity between the photoresist 70 and the flexible dielectric material enables the etch rate to be controlled so as to subsequently etch through the interlevel dielectric material 30 without entirely consuming the flexible dielectric material of the first remaining portion 63.

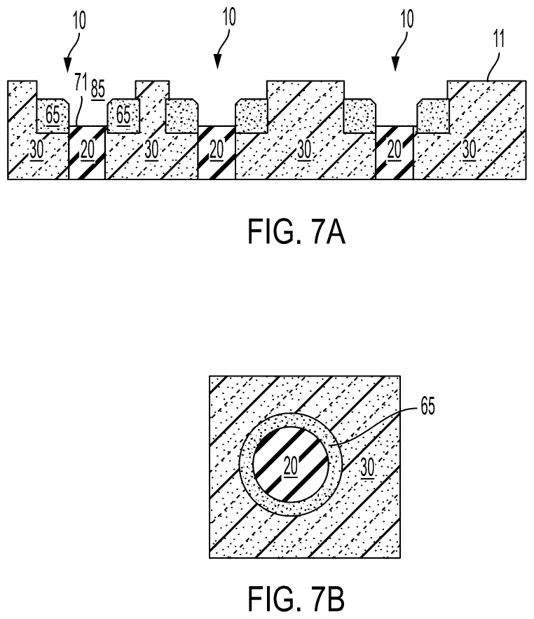

FIG. 7A depicts the contact structure 10 of FIG. 6 after a portion 64 (see FIG. 6) of the first remaining portion 63 of the flexible dielectric material 60 has been etched away by an etching process using the photoresist 70, and after the photoresist 70 has been removed in conjunction with a CMP process that has planarized a top surface 11 of the metallic contact 20, in accordance with embodiments of the present invention.

As a result of etching away the portion 64, the via 80 has been enlarged to become an enlarged via 85, by extended to a top surface 71 of the metallic contact 20, leaving a second remaining portion 65 of the flexible dielectric material.

In one embodiment, the etching process is reactive ion etching (RIE).

FIG. 7B is a top view of the contact structure 10 of FIG. 7A, in accordance with embodiments of the present invention.

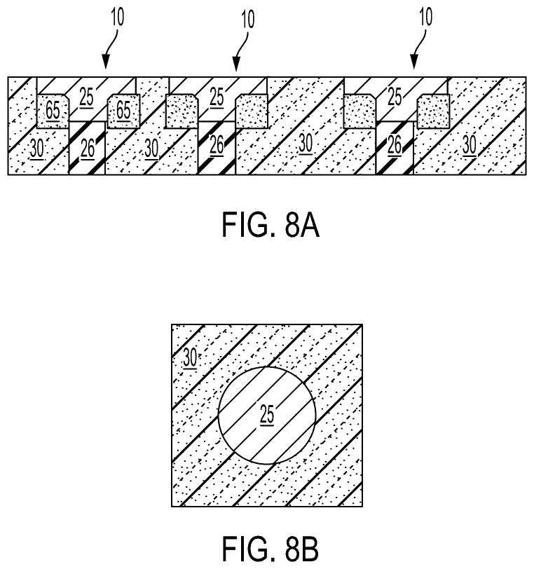

FIG. 8A depicts the contact structure 10 of FIG. 7A after a second metal 25 has been inserted into the via 85 to fill and overflow the via 85, followed by a CMP process to planarize the top surface 11 of the contact structure 10, in accordance with embodiments of the present invention.

In one embodiment, the second metal is inserted into the via 85 by an electroplating process. For example, if the second metal is copper, a copper seed layer may be used to provide nucleation sites for the copper to grow during an electroplating process for electroplating the copper in the via 85. A smooth and strongly textured copper seed layer promotes the development of highly textured, large grains in the electroplated copper film.

The contact structure 10 of FIG. 8A is a final contact structure that includes a metallic contact having a top portion 25 and a bottom portion 26. The top portion 25 comprises the second metal inserted into the via 85. The bottom portion 26 is the metallic contact 20 and comprises the first metal.

In one embodiment, the first metal and the second metal are a same metal.

In one embodiment, the first metal and the second metal different metals.

Thermal reflow of the flexible dielectric material is minimal during subsequent downstream processing steps.

FIG. 8B is a top view of the contact structure 10 of FIG. 7A, in accordance with embodiments of the present invention.

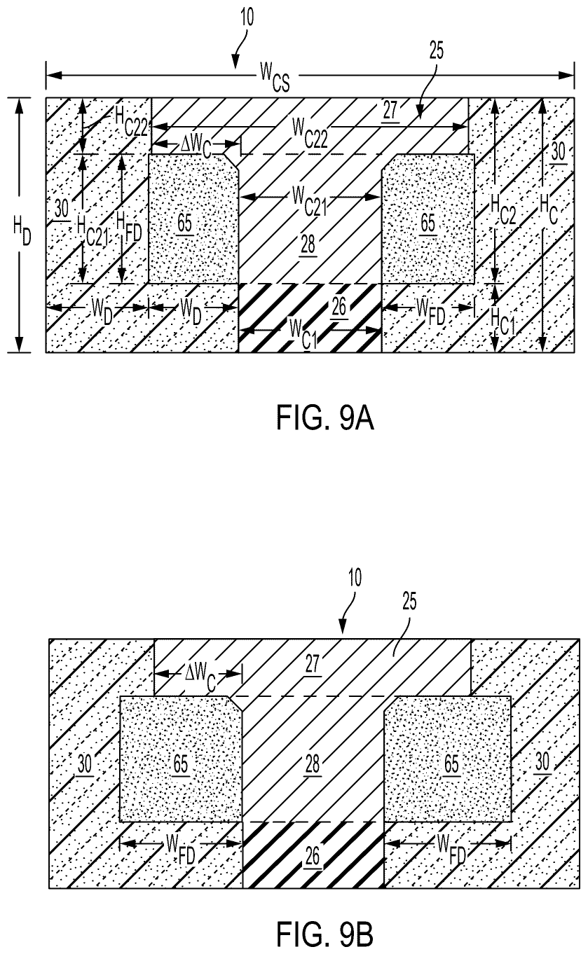

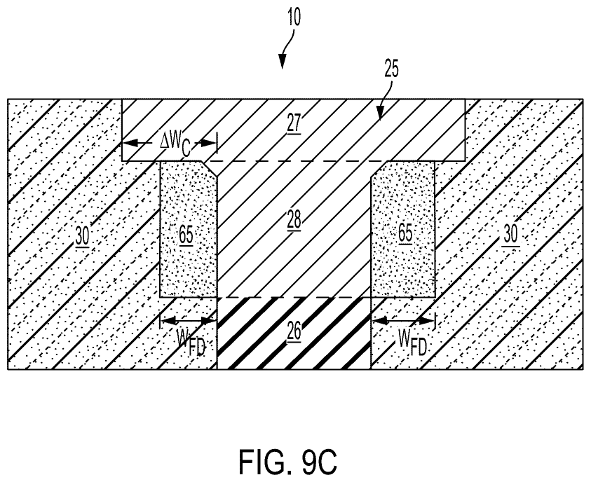

FIGS. 9A, 9B and 9C are each a vertical cross-sectional view of the contact structure 10, including the conductive contact 20 of the multiple conductive contacts in FIG. 8A, surrounding flexible dielectric material 65, and surrounding interlevel dielectric material 30, in accordance with embodiments of the present invention.

The top portion 25 of the metallic contact 20 comprises an upper part 27 and a lower part 28.

The symbols denoting geometric lengths in FIG. 9A also apply to FIGS. 9B and 9C.

Table 1 defines geometric lengths denoted in FIGS. 9A, 9B and 9C.

TABLE 1

| Symbol | Definition |
|---|---|
| W_{CS} | Width of contact structure 10 |
| W_{D} | width of the interlevel dielectric material 30 |
| H_{D} | height of the interlevel dielectric material 30 |
| W_{FD} | width of the flexible dielectric material 65 |
| | which also denotes a radial thickness of flexible |
| | dielectric material if the flexible dielectric |
| | material 65 wraps around the metallic contact |
| | 20 (which comprises top portion 25 and bottom |
| | portion 26) in cylindrical geometry |
| H_{FD} | height of the flexible dielectric material 65 |
| W_{C1} | width of the bottom portion of metallic contact 20 |
| W_{C21} | width of lower part 28 of the top portion 25 |
| | of the metallic contact 20 |
| W_{C22} | width of an upper part 27 of top portion 25 |
| | of the metallic contact 20 |
| H_{C1} | height of the bottom portion 26 of the |
| | metallic contact 20 |
| H_{C2} | height of the top portion 25 of the |
| | metallic contact 20 |
| H_{C} | total height of the metallic contact 20 |
| H_{C21} | height of a lower part 28 of the top portion |
| | 25 of metallic contact 20 |
| H_{C22} | height of an upper part 27 of the top portion |
| | 25 of metallic contact 20 |
| ΔW_{C} | W_{C22} − W_{C21} |

In the embodiment of FIG. 9A, W_{FD}=ΔW_{C}.

FIG. 9B differs from FIG. 9A in that W_{FD}>ΔW_{C} in FIG. 9B.

FIG. 9C differs from FIG. 9A in that W_{FD}<ΔW_{C} in FIG. 9C.

Any of the following embodiments may be combined if physically and logically possible.

In one embodiment, H_{C}=H_{C1}+H_{C2}.

In one embodiment, H_{C21}=H_{FD}.

In one embodiment, H_{C2}=H_{C21}+H_{C22}.

In one embodiment, H_{C2}=H_{FD}+H_{C22}.

In one embodiment, H_{D}=H_{C}.

In one embodiment, H_{D}>H_{C}.

In one embodiment, H_{D}<H_{C}

In one embodiment, W_{D}=W_{C21}.

In one embodiment, W_{D}>W_{C21}.

In one embodiment, W_{D}<W_{C21}.

In one embodiment, W_{D}=W_{C22}.

In one embodiment, W_{D}>W_{C22}.

In one embodiment, W_{D}<W_{C22}.

In one embodiment, W_{C22}=W_{C1}+W_{FD}.

In one embodiment, W_{C22}>W_{C1}+W_{FD}.

In one embodiment, W_{C22}<W_{C1}.+W_{FD}.

In one embodiment, W_{C22}=W_{C1}.

In one embodiment, W_{C22}>W_{C1}.

In one embodiment, W_{C22}<W_{C1}.

In one embodiment, ΔW_{C}=W_{FD}.

In one embodiment, ΔW_{C}>W_{FD}.

In one embodiment, ΔW_{C}<W_{FD}.

In one embodiment, W_{FD}=W_{C22}.

In one embodiment, W_{FD}>W_{C22}.

In one embodiment, W_{FD}<W_{C22}.

In one embodiment, W_{FD}=W_{C21}.

In one embodiment, W_{FD}>W_{C21}.

In one embodiment, W_{FD}<W_{C21}.

In one embodiment, W_{FD}=W_{C1}.

In one embodiment, W_{FD}>W_{C1}.

In one embodiment, W_{FD}<W_{C1}.

In one embodiment, W_{FD}>H_{C1}.

In one embodiment, W_{FD}=H_{C1}.

In one embodiment, W_{FD}<H_{C1}.

In one embodiment, W_{FD}=H_{FD}.

In one embodiment, W_{FD}>H_{FD}.

In one embodiment, W_{FD}<H_{FD}.

In one embodiment, W_{FD}=H_{C1}+H_{FD}.

In one embodiment, W_{FD}>H_{C1}+H_{FD}.

In one embodiment, W_{FD}<H_{C1}+H_{FD}.

In one embodiment, W_{FD}=H_{C1}+H_{C21}.

In one embodiment, W_{FD}>H_{C1}+H_{C21}.

In one embodiment, W_{FD}<H_{C1}+H_{C21}.

In one embodiment, W_{FD}=H_{C1}+H_{C22}.

In one embodiment, W_{FD}>H_{C1}+H_{C22}.

In one embodiment, W_{FD}<H_{C1}+H_{C22}.

In one embodiment, W_{FD}=H_{C}.

In one embodiment, W_{FD}>H_{C}.

In one embodiment, W_{FD}<H_{C}.

In one embodiment, W_{D}=H_{D}.

In one embodiment, W_{D}>H_{D}.

In one embodiment, W_{D}<H_{D}.

The metallic contact 20 and the flexible dielectric material 65 are not limited to a specific type of geometry.

In one embodiment, the metallic contact 20 and the flexible dielectric material 65 each have a cylindrical geometry with respect to direction 15 (see FIG. 2) which is an axial direction for the cylindrical geometry. The direction 15 is normal to each cross section of the metallic contact 20 and to each cross section of the flexible dielectric material 65. Each cross section of the metallic contact 20 is bounded by a circle, and the width of the metallic contact 20 at each cross section is the diameter of circle. Each cross section of the flexible dielectric material 65 is an annulus, and the width of the flexible dielectric material 65 at each cross section is the radial thickness of the annulus.

In one embodiment, the metallic contact 20 and flexible dielectric material 65 each have a rectangular geometry, wherein teach width extends in a direction that is normal to the direction 15.

In one embodiment, the flexible dielectric material 65 differs from the interlevel dielectric material 30.

The top portion 25 of the metallic contact 20 and the bottom portion 26 of the metallic contact 20 comprise a first metal and a second metal, respectively.

In one embodiment, the first metal and the second metal are a same metal.

In one embodiment, the first metal and the second metal are different metals.

In one embodiment, the first metal is any metal in a specified group of metals and the second metal is any metal in the specified group of metals, wherein the first metal and the second metal may be a same metal or may be different metals.

In one embodiment, the specified group of metals comprises copper (Cu), silver (Ag), gold (Au), tungsten (W), titanium (Ti), and zinc (Zn).

In one embodiment, the interlevel dielectric material 30 is tetraethyl orthosilicate (TEOS), SiCN, SiN, SiOCN, fluorinated silicon dioxide (SiOF), or silicon nitride (Si₃N₄).

In one embodiment, the flexible dielectric material 65 is polyimide or polybenzoxazole.

In one embodiment, the flexible dielectric material 65 has a lower modulus of elasticity than does the interlevel dielectric material 30.

In one embodiment, a ratio of the modulus of elasticity of the interlevel dielectric material 30 to the modulus of elasticity of the flexible dielectric material 65 is at least z, where z is a real number in a range of 2 to 20 (e.g., z=2, 5, 10, 15, etc.).

The modulus of elasticity for a given material can vary based on material quality, fabrication method, processing methods, etc,

For polyimide, the modulus of elasticity is in a range of 0.107 to 46.9 GPA.

For polybenzoxazole, the modulus of elasticity is in a range of 0.1 to 0.44 GPa.

For TEOS, the modulus of elasticity is in a range of 45 to 77 GPa.

For SiN, the modulus of elasticity is in a range of 250 to 290 GPa.

For silicon dioxide (SiO₂), the modulus of elasticity is about 70 GPa.

For silicon nitride (Si₃N₄), the modulus of elasticity is about 300 GPa.

In one embodiment, W_{FD}≥W_{FDmin} wherein W_{FDmin} is a void avoidance threshold width defined as a minimum width of the flexible dielectric material 65 at or above which void formation does not occur at an interface between the metallic contact 20 and the flexible dielectric material 65 during the bonding (e.g., annealing) of the metallic contact 20 to another contact (e.g., a contact of a bond device or of a carrier), wherein if W_{FD}<W_{FDmin} the void formation does occur at the interface.

In one embodiment, W_{FD} is about equal to W_{FDmin}, wherein the preceding “about equal to” means that W_{FD} may differ from W_{FDmin} by no more than a tolerance (Tol) due to experimental error in an empirical determination of W_{FDmin}; i.e., W_{FDmin}−Tol≤W_{FD}≤W_{FDmin}+Tol.

In one embodiment, W_{FD} is about greater than W_{FDmin}, wherein the preceding “about greater than” that means that W_{FD}>W_{FDmin}+Tol.

The numerical value of W_{FDmin} may vary based on several factors.

In one embodiment, W_{FDmin} increases as W_{C1} increases.

In one embodiment, W_{FDmin} increases as the modulus of elasticity of the flexible dielectric material 65 increases.

In one embodiment, W_{FDmin} increases as the coefficient of thermal expansion of the metallic contact 20 increases.

In one embodiment, W_{FDmin} may be determined empirically for a given material undergoing a given bonding process (e.g., annealing).

By definition, W_{FDmin} is determined empirically, for a given metallic contact undergoing a given bonding process, by testing in which W_{FD} of the given material is initially at a high value at which there are no voids at the interface between the metallic contact and the flexible dielectric material. Then, W_{FD} of the given material is reduced in successive tests of the given bonding process, and the interface is examined for voids in each test, until W_{FD} reaches a sufficiently low value, namely W_{FDmin}, at which voids appear at the interface.

In one embodiment, W_{FD} is about greater than, or about equal to, an empirically determined void avoidance threshold width W_{FDmin}.

In one embodiment, the contact structure 10 comprises a metallic contact 20; a flexible dielectric material 65 surrounding, and in direct contact with, the metallic contact 20; and an interlevel dielectric material 30 surrounding, and in direct contact with, both the metallic contact 20 and the flexible dielectric material 65, wherein the flexible dielectric material 65 has a lower modulus of elasticity than does the interlevel dielectric material 30, and wherein the flexible dielectric material 65 and the interlevel dielectric material 30 are different dielectric materials.

In one embodiment, the flexible dielectric material 65 is positioned to be compressed in response to a shearing force generated at an interface between the flexible dielectric material 65 and the metallic contact 29 during expansion of the metallic contact 20.

In one embodiment, the flexible dielectric material 65 is an organic dielectric material.

In one embodiment, the organic dielectric material is a polyimide or a polybenzoxazole (PBO).

In one embodiment, the interlevel dielectric material is tetraethyl orthosilicate (TEOS).

In one embodiment, the a ratio of the modulus of elasticity of the interlevel dielectric material 30 to the modulus of elasticity of the flexible dielectric material 65 is at least z, where z is a real number in a range of 2 to 20. In one embodiment, z=2, 5, 10, 15, 20, etc.

In one embodiment, a width (W_{FD}) of the flexible dielectric material 65 about equal to or about greater than an empirically determined void avoidance threshold width (W_{FDmin}).

In one embodiment, the metallic contact 20 comprises a bottom portion 26 and a top portion 25. The top portion 25 comprises an upper part 27 and a lower part 28. The flexible dielectric material 65 is in direct contact with the lower part 28 of the top portion 25 of the metallic contact 20.

In one embodiment, the flexible dielectric material 65 surrounds only the lower part 28 of the top portion 25 of the metallic contact 20 and does not surround any other part or portion of the metallic contact 20.

In one embodiment, a height (H_{FD}) of the flexible dielectric material 65 is equal to a sum of a height (H_{C1}) of the bottom portion 26 of the metallic contact 20 and a height (H_{C22}) of the upper part 27 of the top portion 25 of the metallic contact 20.

In one embodiment, a width (W_{FD}) of the flexible dielectric material 65 is equal to a width (W_{C21}) of the lower part 28 of the top portion 25 of the metallic contact 20.

In one embodiment, a width (W_{FD}) of the flexible dielectric material 65 is equal to a width (W_{C22}) of the upper part 27 of the top portion 25 of the metallic contact 20.

In one embodiment, a width (W_{FD}) of the flexible dielectric material 65 is equal to a width (W_{C1}) of the bottom portion 26 of the metallic contact 20.

In one embodiment, a width (W_{FD}) of the flexible dielectric material 65 is less than a total height (H_{C}) of the metallic contact 20.

In one embodiment, the top portion 25 of the metallic contact 20 and the bottom portion 26 of the metallic contact 20 comprise a first metal and a second metal, respectively, and wherein the first metal and the second metal are different metals.

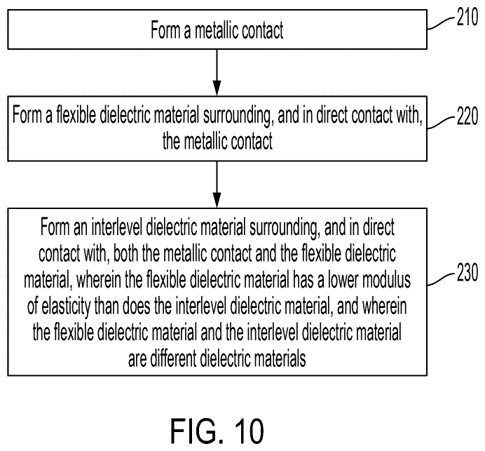

FIG. 10 is a flow chart of a method for forming a contact structure 10, in accordance with embodiments of the present invention. The method of FIG. 10, which includes steps 200-230, is a simplified description of the method of forming a contact structure 10 described in FIGS. 2-9B.

Step 210 forms a metallic contact.

Step 220 forms a flexible dielectric material surrounding, and in direct contact with, the metallic contact.

In one embodiment, step 220 positions the flexible dielectric material to be compressed in response to a shearing force generated at an interface between the flexible dielectric material and the metallic contact during expansion of the metallic contact.

Step 230 forms an interlevel dielectric material surrounding, and in direct contact with, both the metallic contact and the flexible dielectric material, wherein the flexible dielectric material has a lower modulus of elasticity than does the interlevel dielectric material, and wherein the flexible dielectric material and the interlevel dielectric material are different dielectric materials.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A contact structure, comprising:
a metallic contact;
a flexible dielectric material surrounding, and in direct contact with, the metallic contact; and
an interlevel dielectric material surrounding, and in direct contact with, both the metallic contact and the flexible dielectric material,
wherein the flexible dielectric material has a lower modulus of elasticity than does the interlevel dielectric material,
wherein the flexible dielectric material and the interlevel dielectric material are different dielectric materials, and
wherein the flexible dielectric material is positioned to be compressed in response to a shearing force generated at an interface between the flexible dielectric material and the metallic contact during expansion of the metallic contact.

2. The contact structure of claim 1, wherein the flexible dielectric material is an organic dielectric material.

3. The contact structure of claim 2, wherein the organic dielectric material is a polyimide or a polybenzoxazole (PBO).

4. The contact structure of claim 3, wherein the interlevel dielectric material is tetraethyl orthosilicate (TEOS).

5. The contact structure of claim 1, wherein a ratio of the modulus of elasticity of the interlevel dielectric material to the modulus of elasticity of the flexible dielectric material is at least z, where z is a real number in a range of 2 to 70.

6. The contact structure of claim 5, wherein z=10.

7. The contact structure of claim 1, wherein a width of the flexible dielectric material about equal to or about greater than an empirically determined void avoidance threshold width.

8. A contact structure, comprising:
a metallic contact;
a flexible dielectric material; and
an interlevel dielectric material surrounding, and in direct contact with, both the metallic contact and the flexible dielectric material,
wherein the flexible dielectric material has a lower modulus of elasticity than does the interlevel dielectric material,
wherein the flexible dielectric material and the interlevel dielectric material are different dielectric materials,
wherein the metallic contact comprises a bottom portion and a top portion, wherein the top portion comprises an upper part and a lower part, and
wherein the flexible dielectric material is in direct contact with the lower part of the top portion of the metallic contact.

9. The contact structure of claim 8, wherein the flexible dielectric material surrounds only the lower part of the top portion of the metallic contact and does not surround any other part or portion of the metallic contact.

10. The contact structure of claim 9, wherein a height of the flexible dielectric material is equal to a sum of a height of the bottom portion of the metallic contact and a height of the upper part of the top portion of the metallic contact.

11. The contact structure of claim 9, wherein a width of the flexible dielectric material is equal to a width of the lower part of the top portion of the metallic contact.

12. The contact structure of claim 9, wherein a width of the flexible dielectric material is equal to a width of the upper part of the top portion of the metallic contact.

13. The contact structure of claim 9, wherein a width of the flexible dielectric material is equal to a width of the bottom portion of the metallic contact.

14. The contact structure of claim 9, wherein a width of the flexible dielectric material is less than a total height of the metallic contact.

15. The contact structure of claim 8, wherein the top portion of the metallic contact and the bottom portion of the metallic contact comprise a first metal and a second metal, respectively, and wherein the first metal and the second metal are different metals.

16. A method of forming a contact structure, comprising:
forming a metallic contact;
forming a flexible dielectric material surrounding, and in direct contact with, the metallic contact; and
forming an interlevel dielectric material surrounding, and in direct contact with, both the metallic contact and the flexible dielectric material, wherein the flexible dielectric material has a lower modulus of elasticity than does the interlevel dielectric material, and wherein the flexible dielectric material and the interlevel dielectric material are different dielectric materials.

17. The method of claim 16, wherein said forming the flexible dielectric material comprises:
positioning the flexible dielectric material to be compressed in response to a shearing force generated at an interface between the flexible dielectric material and the metallic contact during expansion of the metallic contact.

18. The method of claim 16, wherein a width of the flexible dielectric material about equal to or about greater than an empirically determined void avoidance threshold width.

19. The method of claim 16, wherein the metallic contact comprises a bottom portion and a top portion, wherein the top portion comprises an upper part and a lower part, and wherein the flexible dielectric material is in direct contact with the lower part.

20. The method of claim 19, wherein the flexible dielectric material surrounds only the lower part of the top portion of the metallic contact and does not surround any other part or portion of the metallic contact.
